(19) United States
(12) Patent Application Publication
(10) Pub. No.: US 2009/0267651 A1
(43) Pub. Date: Oct. 29, 2009

(54) SWITCH STATE DETECTOR AND ENCODER

(75) Inventors: Giuseppe Maimone, Muenchen (DE); Rainer Troppmann, Kranzberg (DE)

Correspondence Address: TEXAS INSTRUMENTS INCORPORATED, P O BOX 655474, M/S 3999, DALLAS, TX, 75265, US

(73) Assignee: TEXAS INSTRUMENTS DEUTSCHLAND GMBH, Freising (DE)

(21) Appl. No.: 12/042,708

(22) Filed: Mar. 5, 2008

(30) Foreign Application Priority Data
Mar. 5, 2007 (DE) 10 2007 010 591.8

(51) Int. Cl. H03K 5/22

(52) U.S. Cl. 327/63

(57) ABSTRACT

A switch state detector for use in a system wherein a plurality of n switches (S1, . . . , Sn) produces on a single line (22) a number of discrete voltage levels each representative of one particular state of open and closed switches. The switch state detector comprises a plurality of reference voltage sources each of which corresponds to one of the discrete voltage levels and a set of comparators (C1, . . . , Cm-1) each having a first input connected to the single line (22) and a second input connected to one of the reference voltage sources. The switch state detector further comprises a decoder (24) with inputs receiving the outputs from the comparators (C1, . . . , Cm-1) and with outputs (28) providing a digital representation of the particular state of each of the switches (S1, . . . , Sn). There is further provided an encoder comprising a plurality of n switches (S1, . . . , Sn) and encoding circuitry interconnecting said n switches, as well as a method for communicating an information representative of a particular state of a plurality of n open and closed switches on a single line (22).

This application claims priority from German Patent Application No. 10 2007 010 591.8, filed 5 Mar. 2007.

The invention relates to a switch state detector, to an encoder, and to a method for communicating information on a particular state of a plurality of switches.

### BACKGROUND

In various automotive system applications, many switches are used which are located at different places in the vehicle. Usually there are groups of switches depending on the application. In modem automotive systems, a microcontroller is provided which assumes various control tasks and needs an input about the current state of all or part of the switches used in a system.

The switches are often so-called analog switches, i.e., CMOS transmission gates which are switched by applying a voltage to their gates via a control input. Depending on the gate voltage, the transmission gate is open or closed (ON or OFF). The state of each analog switch, e.g., whether the switch is open or closed, is communicated as an electric signal transmitted via a cable or line to the microcontroller for further processing. In a system with n analog switches, n lines are needed for communicating the switch state information. When the switches are remote from the microcontroller, this leads to high cost for the considerable number of lines which must be extended in the vehicle.

### SUMMARY

The invention provides a solution to the problem described above, by using only a single line or cable to communicate the state of n switches, preferably analog switches.

In one aspect of the invention, an encoder is provided which comprises a plurality of n switches and encoding circuitry interconnecting the n switches to produce a number of discrete voltage levels on a single line, each voltage level representing one particular state of the open and closed switches. For example, in the case of two parallel switches S1 and S2, the voltage is dependent on S1 and S2 both being closed, both open, S1 being open and S2 being closed, or vice-versa. To be able to communicate all possible combinations of switch settings for n switches, m discrete voltage levels are needed with m=2ⁿ.

In a second aspect of the invention, a switch state detector is provided for use with the set of switches, i.e., in a system wherein a plurality of n switches produces a number of discrete voltage levels on a single line, each voltage level representative of one particular state of open and closed switches. The switch state detector comprises a plurality of reference voltage sources, each of which corresponds to one of the discrete voltage levels. The switch state detector further comprises a set of comparators, each having a first input connected to the single line and a second input connected to one of the reference voltage sources, and a decoder with inputs receiving the outputs from the comparators and outputs providing a digital representation of the particular state of each of the switches.

As the particular state of open and closed switches is coded into discrete voltage levels, only these discrete voltage levels must be detected by the switch state detector. Thus, the reference voltage sources are designed to correspond to the discrete voltage levels output by the set of switches. The decoder may be of a very simple design, as it must only output a preset particular state of open and closed switches according to the comparator outputs. There is no need to have a complete analog-to-digital conversion effectuated by an analog-to-digital converter. In a preferred embodiment, one comparator less than the number of discrete voltage levels is used, with the decoder being designed to output a particular switch state when none of the comparators detects a correspondence between its specific reference voltage and the voltage level transmitted on the single line.

Preferably, the decoder in the switch state detector has a further input which receives a strobe signal and provides the digital representation of the particular state of each of the switches upon reception of the strobe signal. In a preferred embodiment, the switch state detector has n outputs, each output corresponding to one of the switches. Thus, the outputs of the switch state detector can be connected to a microcontroller or an electronic control unit in exactly the same way as in prior arrangements, with the n lines communicating the particular state of each switch individually. Therefore, no changes need to be made for the electronic control unit when using the inventive switch state detector that uses only one line for a set of n switches.

In a third aspect, the invention provides a method for communicating an information on a particular state of a plurality of n open and closed switches, in which the following steps are performed: encoding the state of the n switches into a discrete voltage value representative of the particular state of the n open and closed switches; transmitting the discrete voltage value on a single line; comparing the transmitted discrete voltage value representative of one particular state of the n open and closed switches to discrete reference voltage values, each corresponding to one possible state of open and closed switches; and using the results of the comparing step to provide n digital output signals, each representative of the state of one out of the n switches. Preferably, the switches whose states are detected are analog switches.

### BRIEF DESCRIPTION OF THE DRAWINGS

These and other aspects and features of the invention will be apparent to those skilled in the art to which the invention relates from the following detailed description of example embodiments of the invention, taken together with the accompanying drawings, wherein:

FIG. 1 is a simplified circuit diagram for an example encoder comprising a set of switches according to the principles of the invention.

FIG. 2 is a schematic diagram of an example switch state detector according to the principles of the invention.

### DETAILED DESCRIPTION OF EXAMPLE EMBODIMENTS

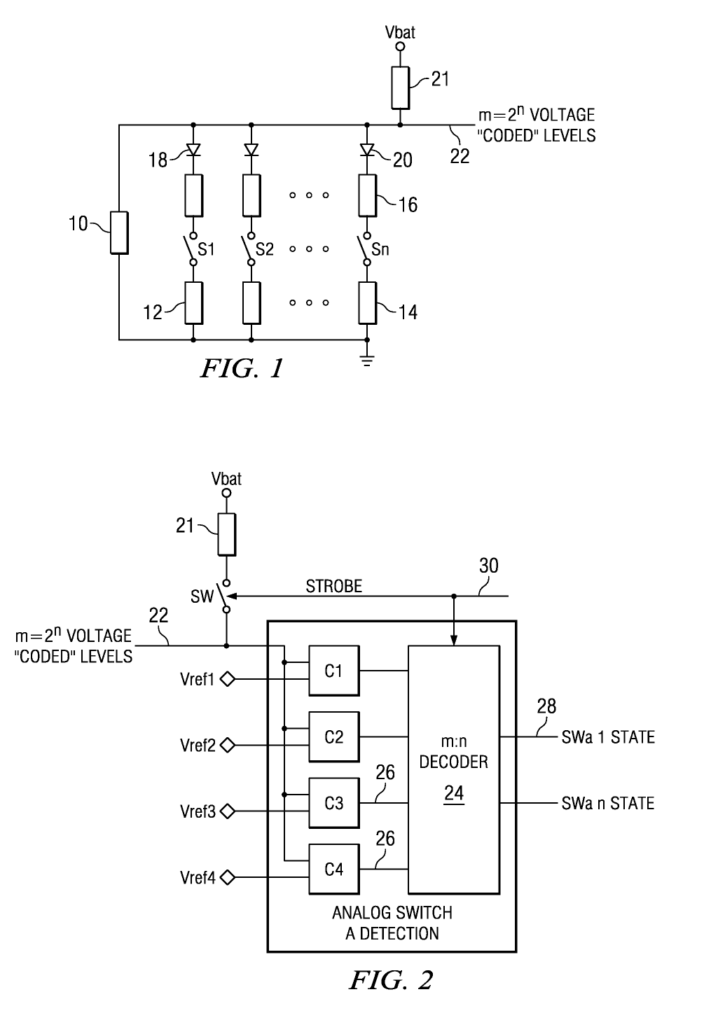

FIG. 1 shows a representative example encoder implementation of the principles of the invention. As shown, the encoder comprises a plurality of n switches S1, S2, . . . , Sn interconnected by encoding circuitry. The encoding circuitry comprises resistors 10, 12, 14, 16, . . . , and diodes 18, 20, . . . , and interconnects the n switches S1, S2, . . . , Sn to produce a number of discrete voltage levels on a single line 22 connected to a voltage source Vbat through a resistor 21. By choosing the values of the resistors appropriately, the discrete voltage level on the single line 22 is representative of the particular state of each of the n switches. The diodes serve to prevent any influence by the load currents on the voltage value on the single line. As is easily understood, with n switches each of which having two possible states, open or closed, there are m=2ⁿ possible combinations of open and closed switches. Therefore, there are m different discrete analog voltages provided on the single output line 22.

The switches S1, . . . , Sn are not connected to any load. The purpose of the arrangement is to generate any of the discrete voltage conditions on line 22 for possibly remote detection and decoding of the switch conditions. The purpose of the diode in each switch branch is for the purpose of decoupling, which may be necessary in an automotive application but not in other applications. As to the resistors in the switch branches, one such resistor in each branch may be sufficient, and one of the branches, e.g., that of switch S1, may even be provided without any resistor. The particular arrangement in FIG. 1, however, offers great flexibility. It may be preferable to stabilize the voltage at voltage source Vbat, depending on the number of switches used in the arrangement.

The analog voltage is transmitted via the single line 22 to a switch state detector, an embodiment according to the principles of the invention of which is shown in FIG. 2. The switch state detector may preferably be located next to a microcontroller or electronic control unit which further processes the information on the particular state of each switch in a digital form.

The switch state detector shown in FIG. 2 comprises a plurality of comparators C1, C2, C3, C4, . . . , each having a first input connected to the single line 22 on which the discrete voltage level representative of one particular state of open and closed switches is transmitted. The number of comparators is chosen to match the number of switches, the conditions of which are to be detected. The illustrated example shows four comparators. A second input of each of comparators is connected to a respective one of a plurality of reference voltage sources Vref1, Vref2, Vref3, Vref4, . . . , which correspond to the possible discrete voltage values obtained by encoding the states of open and closed switches by the encoding circuitry, as explained with respect to FIG. 1. The switch state detector further comprises an m:n decoder 24 which has m−1 inputs 26 and n outputs 28. Each comparator has an output connected to a respective input of decoder 24.

The function of a comparator is well known to persons skilled in the art. The comparators are chosen and connected such that the comparator for which the discrete voltage value on single line 22 corresponds to the input reference voltage Vref1, Vref2, Vref3, Vref4, . . . , will have a high digital output, while all other comparators will have a low digital output, or vice versa. Thus, if one of the reference voltages fed to one of the comparators corresponds to the discrete voltage on the single line 22, the decoder 24 receives one high level signal and m-2 low level signals (or vice-versa) on its inputs. For the illustrated example, only m-1 comparators are used to cover all m possible discrete voltage values, with the m-th value representation handled by a low (or high) level signal on all of the m-1 inputs of the decoder. The decoder 24 may be of very simple construction as there are only m different states at the input 26 to be translated into n predefined high or low signals at the n outputs 28 (SWa 1, . . . , SWa n), each output corresponding to the state of one switch. The n outputs 28 of the decoder can be connected to provide information about the state of the n switches directly to a microprocessor or electronic control unit.

The illustrated decoder 24 embodiment also has a strobe input 30. The strobe input functions to momentarily connect the encoder arrangement to the voltage source Vbat through a switch SW and resistor 21 when the strobe signal is active, decoding the inputs from the m-1 comparators by the decoder 24 into n digital signals output at the decoder outputs 28. By strobing the encoder arrangement, current consumption is reduced.

It will be appreciated that the described embodiments are merely examples of the many ways to implement the invention and that various additions, deletions, substitutions and other modifications may be made therein, without departing from the spirit and scope of the claimed invention.

What is claimed is:

1. A switch state detector for use in a system wherein a plurality of n switches produces on a single line a number of discrete voltage levels, each representative of one particular state of open and closed switches, the switch state detector comprising:
a plurality of reference voltage sources each of which corresponds to one of said discrete voltage levels;
a set of comparators each having a first input connected to said single line and a second input connected to a respective one of said reference voltage sources; and
a decoder with inputs respectively receiving the outputs from said comparators and with outputs providing a digital representation of the particular state of each of said switches.

2. A switch state detector according to claim 1, wherein said plurality of n switches produces on said single line m discrete voltage levels, with m=2ⁿ.

3. A switch state detector according to claim 2, wherein said set of comparators comprises m-1 comparators.

4. A switch state detector according to claim 1, wherein said decoder has n outputs, each output corresponding to one of said n switches.

5. A switch state detector according to claim 1, wherein said decoder has a further input receiving a strobe signal and provides said digital representation of the particular state of each of said switches upon reception of said strobe signal, the strobe signal further controlling a switch to connect the single line momentarily to a voltage source through a fixed resistor.

6. A switch state detector according to claim 1, wherein the switches are analog switches.

7. An encoder comprising a set of n switches and encoding circuitry interconnecting said n switches and producing on a single line a number of discrete voltage levels each representative of one particular state of the open and closed switches.

8. An encoder according to claim 7, wherein said plurality of n switches produces on said single line m discrete voltage levels, with m=2ⁿ.

9. An encoder according to claim 7, wherein the encoding circuitry comprises a plurality of diodes, the anode of each diode being connected to the single line and the cathode of each diode being connected to a respective one of the switches.

10. An encoder according to claim 7, wherein the switches are analog switches.

11. A method for communicating information representative of a particular state of a plurality of n open and closed switches, the method comprising:
encoding the state of the n switches into a discrete voltage value representative of said particular state of the n open and closed switches;
transmitting the discrete voltage value on a single line;
comparing the transmitted discrete voltage value representative of one particular state of the n open and closed switches to discrete reference voltage values each corresponding to one possible state of open and closed switches; and
using the results of the comparing step to provide n digital output signals, each representative of the state of a respective one of the n switches.
